(19) United States
(12) Patent Application Publication
(10) Pub. No.: US 2026/0059746 A1
(43) Pub. Date: Feb. 26, 2026

(54) SEMI-FLOATING GATE TRANSISTOR AND MANUFACTURING METHOD FOR THE SAME

(71) Applicant: Shanghai Huali Integrated Circuit Corporation, Shanghai (CN)

(72) Inventors: Shiling Yang, Shanghai (CN); Tianpeng Guan, Shanghai (CN); Yanfei Ma, Shanghai (CN)

(73) Assignee: Shanghai Huali Integrated Circuit Corporation, Shanghai (CN)

(21) Appl. No.: 19/283,855

(22) Filed: Jul. 29, 2025

(30) Foreign Application Priority Data
Aug. 20, 2024 (CN) 202411146714.3

(51) Int. Cl. H10B 41/30

(52) U.S. Cl. CPC H10B 41/30

(57) ABSTRACT

The present application discloses a semi-floating gate transistor, and a storage unit includes semi-floating gate trenches formed in selected areas of a plurality of first active areas arranged in parallel. Semi-floating gate conductive material layers are filled in the semi-floating gate trenches and extend outside the semi-floating gate trenches. Semi-floating gate split trenches are formed at tops of first field oxides, and fully isolate, by cutting, the semi-floating gate conductive material layers at both sides. Control gate dielectric layers and control gate conductive material layers are formed at the first sides and second sides, and top surfaces of the semi-floating gate conductive material layers, and the control gate conductive material layers also completely fills the semi-floating gate split trenches at both sides of the wrapped semi-floating gate conductive material layers. The present application also discloses a method of manufacturing a semi-floating gate transistor.

### CROSS-REFERENCE TO RELATED APPLICATIONS

This application claims priority to Chinese patent application No. 202411146714.3, filed on Aug. 20, 2024, the disclosure of which is incorporated herein by reference in its entirety.

### TECHNICAL FIELD

The present application relates to a method of manufacturing a semiconductor integrated circuit, and in particular to a semi-floating gate (SFG) transistor. The present application also relates to a method of manufacturing a semi-floating gate transistor.

### BACKGROUND

A semi-floating gate transistor, which does not use capacitance that is a bottleneck in the development of a conventional DRAM, can be integrated with standard logic processes and is more easily miniatured, so it is a promising DRAM. In a functional design of a device, semi-floating gate poly gates are isolated from each other by shallow trench isolation (STI) and are charged and discharged by applying a voltage to the semi-floating gate poly gates by a control gate to realize transition between a logic-1 state and a logic-0 state.

In a semi-floating gate process in which storage unit areas, i.e., array areas and logic areas, are compatible, a semi-floating gate oxide layer (gate OX) is grown after a U-trench, i.e., a semi-floating gate trench, is formed, then first deposition (dep) of semi-floating gate poly is to fill the U-trench, then a semi-floating gate dielectric window (C-window) etch (ET) process is performed to etch a semi-floating gate oxide layer, second deposition of semi-floating gate poly realizes contact of the semi-floating gate poly with a semiconductor material of an active area, such as Si, to form a PN junction, and finally by blanket etch, semi-floating gate poly in an array area is etched to a thickness of 110 Å, thereby obtaining final semi-floating gate poly gates which, at this point, are isolated from each other by a hard mask layer (HM) at the top of STI, then a control gate oxide layer is grown, and a control gate polysilicon silicon (poly) is deposited.

In the existing method, a U-trench formation process comprises U-trench X etching which is etching in an X direction and U-trench Y etching which is etching in a Y direction. The X direction is an extension direction of STI and the Y direction is a direction for arranging STI and an active area. The U-trench X etching first forms a hard mask (HM) layer, and then, etching is performed to form a trench pattern of the HM, which extends in the X direction and is located at the top of the active area.

The U-trench Y etching is to perform pattern definition in the Y-direction and etch silicon in an active area of a defined area to form a semi-floating gate trench; and, HM subjected to Y-direction pattern definition also has etched partial thickness.

The existing method has the following process risks.

Semi-floating gate poly gates being isolated from each other is a prerequisite to ensure a normal operation of a device. The existing process utilizes STI HM as isolation, and effective isolation depends on a relation between an effective amount of HM remaining in the STI area after the U-trench Y etching forming U-trenches and an amount of a semi-floating gate poly gate, e.g., 110 Å, remaining at a top of an active area after semi-floating gate ploy gates are etched. Only when a remaining amount of STI HM is greater than 110 Å, it can be guaranteed that the semi-floating gate poly gates are not shorted, posing a challenge for process stability of both U-trench Y etching and semi-floating gate poly gate deposition and etching, with a small process window.

Since a change of charge in the semi-floating gate poly gates changes a logic-“1” state and a logic-“0” state, it is required that the semi-floating gate poly gates are changed as much as possible when programing, i.e., writing, to distinguish the logic-“1” state from the logic-“0” state and to increase a device speed. However, at present, an effective coupling area of the semi-floating gate poly gate with a control poly gate is only at the top of the semi-floating gate poly gate, attracting limited charge, and still, coupling further needs to be improved.

### BRIEF SUMMARY

According to some embodiments in this application, a semi-floating gate transistor disclosed in this application comprising: a plurality of storage units formed in a storage unit area.

In the storage unit area, first active areas defined by first field oxides are formed on a semiconductor substrate, the first active areas are arranged in parallel, and the first field oxides are arranged in parallel.

An extension direction of the first active areas is an X-direction, and a direction in which the first active areas are arranged alternately with the first field oxides is a Y-direction.

The storage units comprise semi-floating gate trenches formed in selected areas of the first active areas.

Semi-floating gate dielectric layers are formed at inner surfaces of the semi-floating gate trenches, the semi-floating gate dielectric layers further extending to surfaces of the first active areas outside the semi-floating gate trenches and being formed with semi-floating gate dielectric windows.

Semi-floating gate conductive material layers are filled in the semi-floating gate trenches and extend outside the semi-floating gate trenches, and at the semi-floating gate dielectric windows, the semi-floating gate conductive material layers contact with surfaces of the first active areas.

Semi-floating gate split trenches are formed in tops of the first field oxides, the semi-floating gate split trenches fully isolate, by cutting, the semi-floating gate conductive material layers at both sides, and first sides and second sides of the semi-floating gate conductive material layers are exposed to sides of the semi-floating gate split trenches at both sides.

Control gate dielectric layers and control gate conductive material layers are formed at the first sides and second sides, and top surfaces of the semi-floating gate conductive material layers, the control gate conductive material layers wrapping the semi-floating gate conductive material layers from the first sides and second sides, and top surfaces of the semi-floating gate conductive material layers, and the control gate conductive material layers also completely filling the semi-floating gate split trenches at both sides of the wrapped semi-floating gate conductive material layers.

The control gate conductive material layers have first sides and second sides extending in the Y direction.

Third sides of the semi-floating gate conductive material layers and the first sides of the control gate conductive material layers are aligned vertically, and fourth sides of the semi-floating gate conductive material layers and the second sides of the control gate conductive material layers are aligned vertically.

In some cases, second trenches are also formed in both sides of the semi-floating gate trenches, the semi-floating gate trenches and the second trenches in both sides are communicated together and aligned along sides in the Y-direction; and the second trenches are recessed in the first field oxides, and bottom surfaces of the second trenches are higher than bottom surfaces of the semi-floating gate trenches.

In some cases, the first field oxides use shallow trench isolation filled in a shallow trench.

Bottom areas of the semi-floating gate split trenches further comprise partial thicknesses of removing areas of the first field oxides, and bottom surfaces of the semi-floating gate split trenches are lower than the top surfaces of the shallow trenches.

The second trenches are constituent portions of the semi-floating gate split trenches, and the bottom surfaces of the semi-floating gate split trenches at the second trenches are lower than the bottom surfaces outside the second trenches.

In some cases, a selection gate conductive material layer is formed at a top of the first active area outside the second sides of the control gate conductive material layers, a first side of the selection gate conductive material layer is isolated from the second sides of the control gate conductive material layers and the fourth sides of the semi-floating gate conductive material layer by a first inter-gate dielectric layer.

The selection gate conductive material layer is isolated from the top surface of the first active area by a selection gate dielectric layer.

In some cases, further comprised are:
a lightly doped source-drain area with a first conductive type formed in a surface area of the first active area and a doped channel area with a second conductive type located at a bottom of the lightly doped source-drain area.

The semi-floating gate trenches pass through the lightly doped source-drain area and bottom surfaces of the semi-floating gate trenches enter the channel area.

First sidewalls are formed on the first sides of the control gate conductive material layers and the third sides of the semi-floating gate conductive material layers, a heavily doped source area with a first conductive type is formed in the lightly doped source-drain area outside the first sidewalls, and the source area and sides of the first sidewalls are self-aligned.

A second sidewall is formed on a second side of the selection gate conductive material layer, a heavily doped drain area with a first conductive type is formed in the lightly doped source-drain area outside the second sidewall, and the drain area and a side of the second sidewall are self-aligned.

In some cases, the control gate conductive material layers of the storage units aligned in the Y direction are connected together to form a first conductive material strip structure.

In some cases, the semi-floating gate conductive material layers extending outside the semi-floating gate trenches have a thickness with a minimum value less than 110 Å.

In some cases, a material of the semiconductor substrate comprises silicon.

A material of the semi-floating gate conductive material layers comprises polysilicon.

A material of the control gate conductive material layers comprises polysilicon.

A material of the selection gate conductive material layer comprises polysilicon.

According to some embodiments in this application, a method for manufacturing a a semi-floating gate transistor is disclosed in the following steps:
providing a semiconductor substrate in which in a storage unit area, first active areas defined by first field oxides are formed on the semiconductor substrate, the first active areas being arranged in parallel, and the first field oxides being arranged in parallel; and an extension direction of the first active areas being an X-direction, and a direction in which the first active areas are arranged alternately with the first field oxides being a Y-direction;
performing a Y-direction trench patterned etching to form semi-floating gate trenches in selected areas of the first active areas, the semi-floating gate trenches having first sides and second sides extending in the X-direction, and third sides and fourth sides extending in the Y-direction; and the third sides and fourth sides of the semi-floating gate trenches being defined by a photomask, and the first sides and second sides of the semi-floating gate trenches being defined by self-alignment of the first field oxides at both sides;
sequentially forming semi-floating gate dielectric layers and semi-floating gate conductive material layers, the semi-floating gate dielectric layers being formed on the inner surfaces of the semi-floating gate trenches, and the semi-floating gate dielectric layers also extending to the surfaces of the first active areas outside the semi-floating gate trenches and being formed with semi-floating gate dielectric windows; and the semi-floating gate conductive material layers being filled in the semi-floating gate trenches and extending outside the semi-floating gate trenches, and at the semi-floating gate dielectric windows, the semi-floating gate conductive material layers contacting with the surfaces of the first active areas;
performing X-direction trench patterned etching to remove the semi-floating gate conductive material layers of tops of the first field oxides and form semi-floating gate split trenches, the semi-floating gate split trenches fully isolating, by cutting, the semi-floating gate conductive material layers at both sides, and first sides and second sides of the semi-floating gate conductive material layers being exposed to sides of the semi-floating gate split trenches at both sides; and the sides of the semi-floating gate split trenches extending in the X direction and being defined by a photomask;
sequentially forming control gate dielectric layers and control gate conductive material layers on the first sides and second sides, and top surfaces of the semi-floating gate conductive material layers, the control gate conductive material layers wrapping the semi-floating gate conductive material layers from the first sides and second sides, and top surfaces of the semi-floating gate conductive material layers, and the control gate conductive material layers also completely filling the semi-floating gate split trenches at both sides of the wrapped semi-floating gate conductive material layers; and
performing control gate patterned etching, the control gate patterned etching comprising etching the control gate conductive material layers to form first sides and second sides of the control gate conductive material layers extending in the Y direction, and etching the semi-floating gate conductive material layers to form third sides and fourth sides of the semi-floating gate conductive material layers, the third sides of the semi-floating gate conductive material layers and the first sides of the control gate conductive material layers being aligned vertically, and the fourth sides of the semi-floating gate conductive material layers and the second sides of the control gate conductive material layers being aligned vertically.

In some cases, the Y-direction trench patterned etching also simultaneously etches the first field oxides at both sides of the semi-floating gate trenches and forms second trenches, the semi-floating gate trenches and the second trenches at both sides are communicated together and aligned along sides in the Y-direction; and bottom surfaces of the second trenches are higher than bottom surfaces of the semi-floating gate trenches. In some cases, the first field oxides use shallow trench isolation filled in a shallow trench. The X-direction trench patterned etching also removes partial thicknesses of the first field oxides after etching away the semi-floating gate conductive material layers, so that the bottom surfaces of the semi-floating gate split trenches are lower than the top surfaces of the shallow trenches.

The second trenches are constituent portions of the semi-floating gate split trenches, and the bottom surfaces of the semi-floating gate split trenches at the second trenches are lower than the bottom surfaces outside the second trenches.

In some cases, further comprised is:
a step of forming a selection gate dielectric layer, a first inter-gate dielectric layer, and a selection gate conductive material layer; the selection gate conductive material layer being formed at tops of the first active areas outside the second sides of the control gate conductive material layers, and first side of the selection gate conductive material layer being isolated from second sides of the control gate conductive material layers and fourth sides of the semi-floating gate conductive material layers by the first inter-gate dielectric layer.

The selection gate conductive material layer is isolated from a top surface of the first active area by the selection gate dielectric layer.

In some cases, in the provided semiconductor substrate, a lightly doped source-drain area with a first conductive type is formed in a surface area of the first active area and a doped channel area with a second conductive type located at a bottom of the lightly doped source-drain area.

The semi-floating gate trenches pass through the lightly doped source-drain area and bottom surfaces of the semi-floating gate trenches enter the channel area.

Further comprised are steps of:
forming first sidewalls on the first sides of the control gate conductive material layers and third sides of the semi-floating gate conductive material layers, and forming second sidewalls on second side of the selection gate conductive material layer; and
performing heavily doped source-drain implantation with a first conductive type for self-alignment in the lightly doped source-drain area outside the first sidewalls to form a source area and self-alignment in the lightly doped source-drain area outside the second sidewalls to form a drain area.

In some cases, after the control gate patterned etching is completed, the control gate conductive material layers of the storage units aligned in the Y-direction are connected together to form a first conductive material strip structure.

In some cases, before performing the X-direction trench patterned etching, further comprised is:
performing blanket etch for the semi-floating gate conductive material layers to thin thicknesses of the semi-floating gate conductive material layers.

In some cases, the semi-floating gate conductive material layers extending outside the semi-floating gate trenches have a thickness with a minimum value less than 110 Å.

In some cases, a material of the semiconductor substrate comprises silicon.

A material of the semi-floating gate conductive material layers comprises polysilicon.

A material of the control gate conductive material layers comprises polysilicon.

A material of the selection gate conductive material layer comprises polysilicon.

In some cases, in the X-direction trench patterned etching, a photomask defining the shallow trench is used to define an area for forming the semi-floating gate split trenches.

In the prior art, a semi-floating gate conductive material layer is formed on a surface of a semiconductor substrate after completion of X- and Y-direction trench patterned etching, the X-direction trench patterned etching causes a top surface of an active area, i.e., a first active area, in a storage unit area to be lower than a top surface of a hard mask layer at a top of a first field oxide, and after the semi-floating gate conductive material layer is filled, the difference between a top surface of the semi-floating gate conductive material layer and the top surface of the hard mask layer at the top of the first field oxide is adjusted by performing maskless-defined blanket etch on the semi-floating gate conductive material layer. If the top surface of the semi-floating gate conductive material layer is higher than the top surface of the hard mask layer at the top of the first field oxide, the top surface of the hard mask layer at the top of the first field oxide has a remained semi-floating gate conductive material layer, and the semi-floating gate conductive material layers in two adjacent first active area-heavy layers are connected together at the top of the hard mask layer at the top of the first field oxide; and therefore, a process window for controlling isolation between the semi-floating gate conductive material layers in two adjacent first active areas by blanket etch of the semi-floating gate conductive material layer is relatively small, with a poor process stability.

However, in the present application, the semi-floating gate conductive material layers are directly formed in the semi-floating gate trenches and extend outside the semi-floating gate trenches, and X-direction patterns of the semi-floating gate conductive material layers, i.e., the first sides and the second sides, are defined by the sides of the semi-floating gate split trenches formed at the tops of the first field oxides; and since the semi-floating gate split trenches themselves are trenches formed by splitting the semi-floating gate conductive material layers, the semi-floating gate split trenches can fully isolate, by cutting, the semi-floating gate conductive material layers at both sides, and it can be ensured that semi-floating gate conductive material layers on two adjacent first active areas are not connected together; and the semi-floating gate split trenches only need to fully isolate, by cutting, the semi-floating gate conductive material layers, and are not limited by the thickness of the semi-floating gate conductive material layer of the surface of the first active area and the thickness of the hard mask layer of the top of the first field oxide, so the present application can increase a process window.

The semi-floating gate split trenches provided by the present application can expose the first sides and second sides of the semi-floating gate conductive material layers while splitting the semi-floating gate conductive material layers, and the control gate conductive material layers of the present application further cover on the first sides and second sides of the semi-floating gate conductive material layers, so that the control gate conductive material layers can wrap the semi-floating gate conductive material layers from the first sides and second sides, and top surfaces of the semi-floating gate conductive material layers; and compared with the existing method in which the control gate conductive material layers can cover the semi-floating gate conductive material layers only from the top surfaces of the semi-floating gate conductive material layers, the present application increases the area of the control gate conductive material layers covering the semi-floating gate conductive material layers, i.e., the coupling area between the control gate conductive material layers and the semi-floating gate conductive material layers increases, so, during writing, i.e. programming, the amount of charge written to the semi-floating gate conductive material layers increases, thereby increasing read-“1” performance of a device.

In addition, after the control gate conductive material layers of the present application cover the semi-floating gate conductive material layers from the sides, the minimum distance between the control gate conductive material layers and the channel areas is the distance between the lowest position of the control gate conductive material layers located at the sides of the semi-floating gate conductive material layers and the channel areas, and that distance is smaller than the distance between the lowest position of the control gate conductive material layers located at the top surfaces of the semi-floating gate conductive material layers and the channel areas, and thus, a voltage drop from the control gate conductive material layers to the channel areas can be reduced, thereby being capable of increasing an effective voltage applied on the channel areas.

### BRIEF DESCRIPTION OF THE DRAWINGS

The present application is described in further detail below in combination with figures and detailed description:

FIGS. 1A-FIG. 5B are schematic views of device structures in steps of an existing method of manufacturing a semi-floating gate transistor; and

FIGS. 6A-FIG. 11D are schematic views of device structures in steps of a method of manufacturing a semi-floating gate transistor of an embodiment of the present application.

### DETAILED DESCRIPTION OF THE DISCLOSURE

The embodiments of the present application are formed by analyzing technical problems in an existing method, and before introducing the embodiment of the present application in detail, the existing method is briefly introduced.

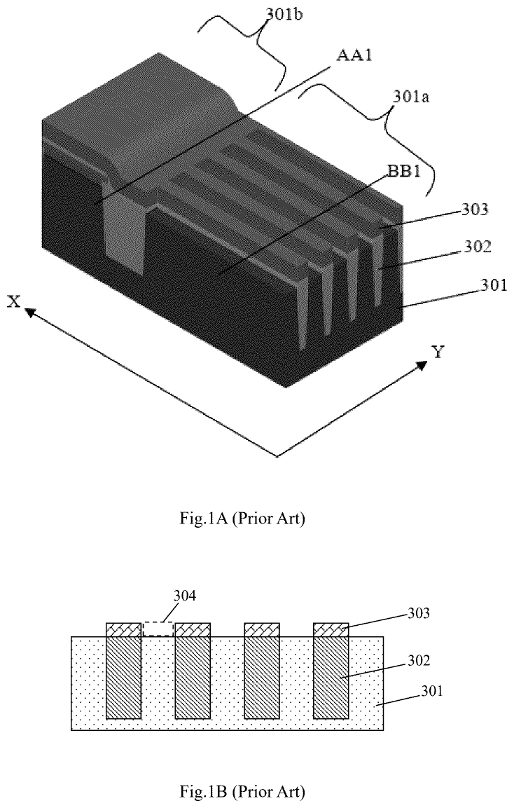

FIGS. 1A-FIG. 5B are schematic views of device structures in steps of an existing method of manufacturing a semi-floating gate transistor; and the existing method of manufacturing a semi-floating gate transistor comprises the following steps.

referring to FIG. 1A, a semiconductor substrate 301 is provided, in which in a storage unit area 301a, active areas defined by field oxides 302 are formed on the semiconductor substrate 301, the active areas being arranged in parallel, and the field oxides 302 being arranged in parallel; an extension direction of the active areas being an X-direction, and a direction in which the active areas are arranged alternately with the field oxides 302 being a Y-direction.

Referring to FIG. 1A, on the semiconductor substrate 301, both a storage unit area 301a and a logic area 301b are comprised, where in FIG. 1A, the storage unit area 301a and the logic area 301b are separated by a line AA1. The storage unit is formed in the storage unit area 301a and a logic device is formed in the logic area 301b.

Typically, the field oxides 302 use shallow trench isolation filled in a shallow trench.

An X-direction trench patterned etching, i.e., U-trench X etching, is performed; the U-trench X etching first forms a hard mask layer 303; and then, the hard mask layer 303 is subjected to patterned etching. After the U-trench X etching, the hard mask layer 303 of the top of the active area of the storage unit area 301a is removed to form a trench 304.

FIG. 1A is a schematic view of a three-dimensional structure.

FIG. 1B shows a schematic view of a sectional structure along a line BB1 in FIG. 1A, showing only a sectional structure view along the Y direction, and for the trench 304, please refer to FIG. 1B.

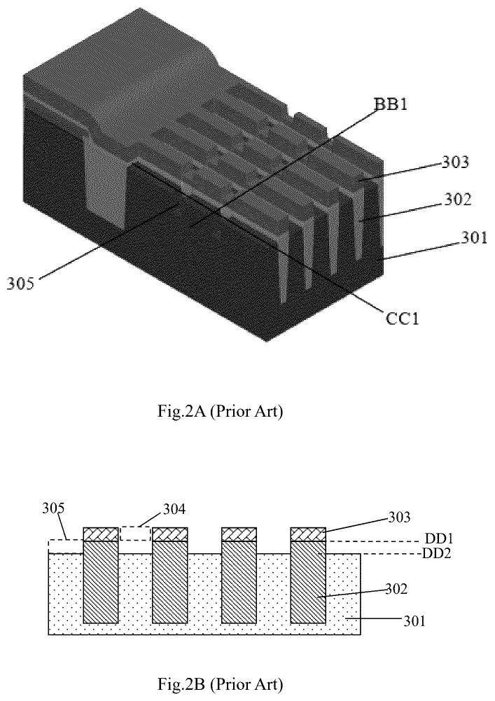

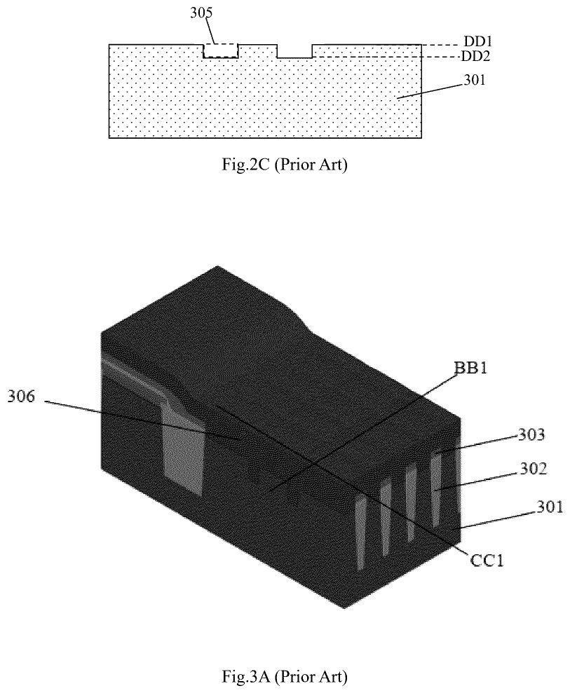

Referring to FIG. 2A, Y-direction trench patterned etching, i.e., U-trench Y etching, is performed; and the U-trench Y etching is etching to form a semi-floating gate trench 305 after defining a pattern extending in the Y-direction. The semi-floating gate trench 305 is obtained by etching a semiconductor material, such as silicon, of the semiconductor substrate 301 of the active area in the area where a defined Y-direction graph and a previously opened active area intersect.

FIG. 2A is a schematic view of a three-dimensional structure.

FIG. 2B shows a schematic view of a sectional structure along a line BB1 in FIG. 2A, showing only a sectional structure view along the Y direction, and FIG. 2C shows a schematic view of a sectional structure along a line CC1 in FIG. 2A, showing only a sectional structure view along the X direction.

Referring to FIG. 2C, a dashed line DD2 corresponds to a position of a bottom surface of a semi-floating gate trench 305; and a dashed line DD1 corresponds to a position of a top surface of an active area outside the semi-floating gate trench 305, i.e., a position of a top surface of the semi-floating gate trench 305.

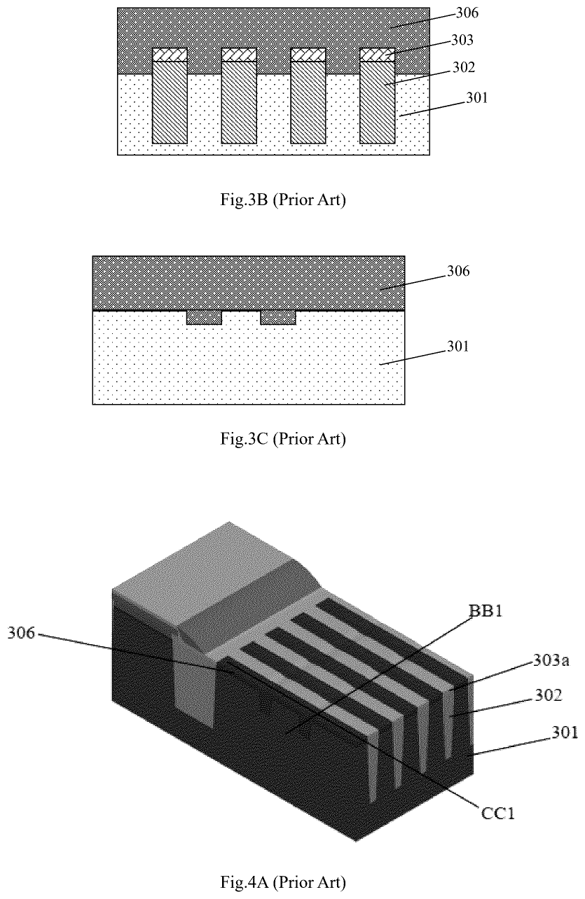

Referring to FIG. 3A, semi-floating gate dielectric layers (not shown) and semi-floating gate polysilicon layers 306 are formed.

FIG. 3A is a schematic view of a three-dimensional structure.

FIG. 3B shows a schematic view of a sectional structure along a line BIB1 in FIG. 3A; and FIG. 3C shows a schematic view of a sectional structure along a line CC1 in FIG. 3A.

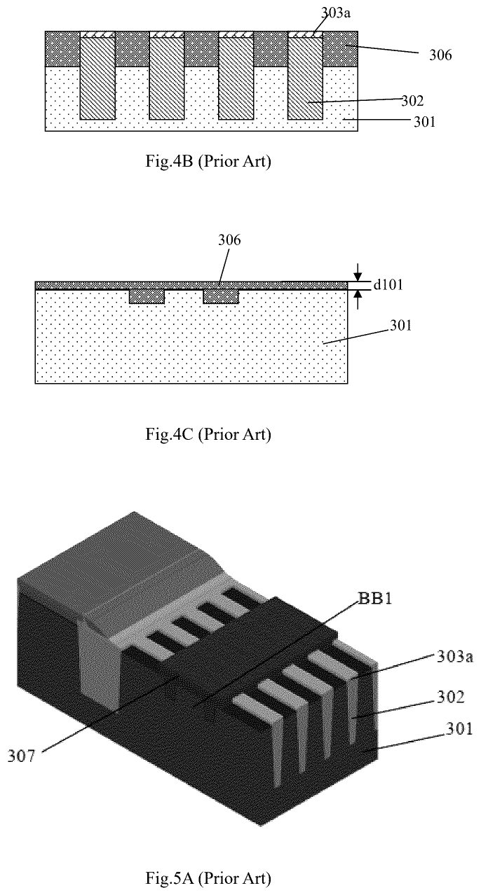

Referring to FIG. 4A, blanket etch of polysilicon is performed to lower the surfaces of the semi-floating gate polysilicon layers 306.

FIG. 4A is a schematic view of a three-dimensional structure.

FIG. 4B shows a schematic view of a sectional structure along a line BB1 in FIG. 4A; and FIG. 4C shows a schematic view of a sectional structure along a line CC1 in FIG. 4A.

Referring to FIG. 4C, the semi-floating gate polysilicon layers 306 on the surface of the active area outside the semi-floating gate trench 305 have a thickness d101 which needs to be reduced to about 110 Å.

Referring to FIG. 4B, blanket etch of polysilicon causes a loss in a thickness of the hard mask layer 303 to form a thinner hard mask layer 303a. Semi-floating gate polysilicon layers 306 at tops of different active areas need to be isolated by the hard mask layer 303a.

However, in the existing method, to realize isolation of semi-floating gate polysilicon layers 306 between different active areas, a process window is very small, easily causing shorting of the semi-floating gate polysilicon layers 306, and the stability for deposition and an etching process for the semi-floating gate polysilicon layers 306 is challenging, and a process window is small.

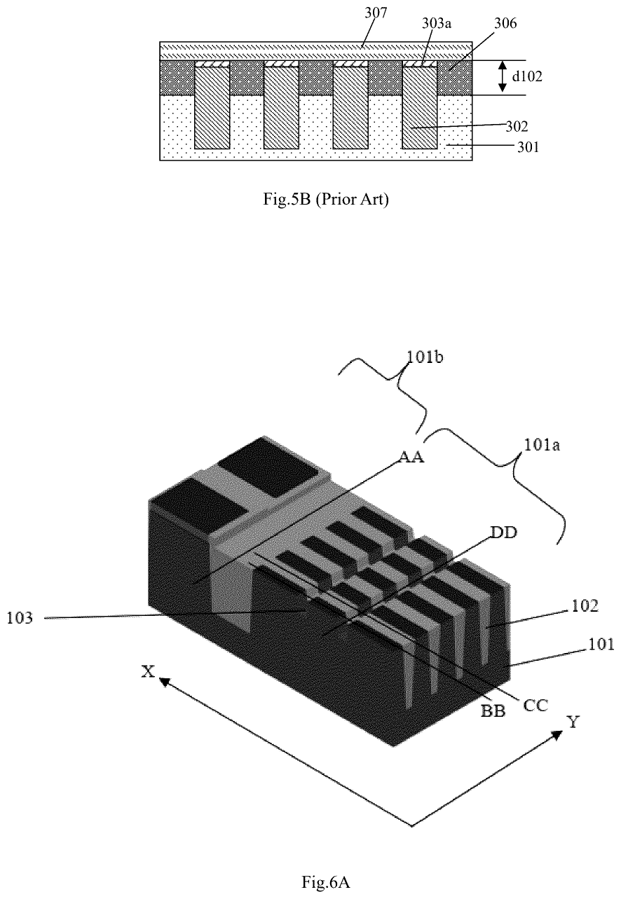

Referring to FIG. 5A, control gate dielectric layers (not shown) and control gate polysilicon layers 307 are formed sequentially.

Control gate patterned etching is performed, the control gate patterned etching comprising sequentially etching the control gate polysilicon layers 307 and bottoms of the semi-floating gate polysilicon layers 306. Referring to FIG. 5A, after the control gate patterned etching is completed, the control gate polysilicon layers 307 of the storage units aligned in the Y direction are connected together to form a polysilicon strip.

FIG. 5A shows a three-dimensional view after the control gate patterned etching is completed; and FIG. 5B shows a schematic view of a cross-sectional structure along a line BB1 in FIG. 5A.

Referring to FIG. 5B, the control gate polysilicon layers 307 cover the bottom of the semi-floating gate polysilicon layers 306 from the top. Bottom surfaces of the semi-floating gate polysilicon layers 306 are locations of top surfaces of channel areas, and a distance between the control gate polysilicon layers 307 and the channel areas is d102.

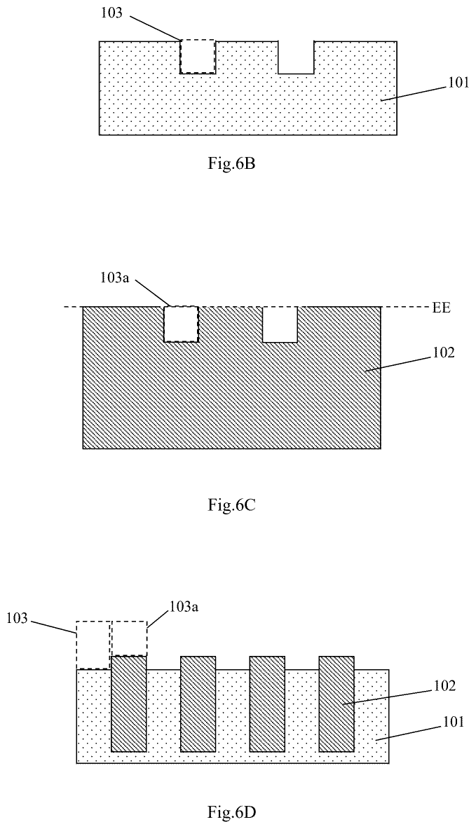

Referring to FIG. 6A to FIG. 11D, they are schematic views of device structures in steps of a method of manufacturing a semi-floating gate transistor according to a method of an embodiments of the present application; the method of manufacturing a semi-floating gate transistor according to the method of the embodiment of the present application comprises the following steps:

step S101, referring to FIG. 6A, providing a semiconductor substrate 101 in which in a storage unit area 101a, first active areas defined by first field oxides 102 are formed on the semiconductor substrate 101, the first active areas being arranged in parallel, and the first field oxides 102 being arranged in parallel; and an extension direction of the first active areas being an X-direction, and a direction in which the first active areas are arranged alternately with the first field oxides 102 being a Y-direction.

In the method of the embodiment of the present application, the first field oxide 102 uses shallow trench isolation (STI) filled in a shallow trench.

The method comprises step S102 of, referring to FIG. 6A, performing Y-direction trench patterned etching to form semi-floating gate trenches 103 in selected areas of the first active areas, the semi-floating gate trenches having first sides and second sides extending in the X-direction, and third sides and fourth sides extending in the Y-direction; and the third sides and fourth sides of the semi-floating gate trenches 103 being defined by a photomask, and the first sides and second sides of the semi-floating gate trenches 103 being defined by self-alignment of the first field oxides 102 at both sides. The Y-direction trench patterned etching, i.e., U-trench Y etching, enables a trench pattern extending in the Y-direction.

FIG. 6A is a schematic view of a three-dimensional structure.

FIG. 6B shows a schematic view of a sectional structure along a line BB in FIG. 6A, showing only a sectional structure along the extension direction of the first active areas.

FIG. 6C shows a schematic view of a sectional structure along a line CC in FIG. 6A, showing only a sectional structure view along an extension direction of the first field oxides.

FIG. 6D shows a schematic view of a sectional structure along a line DD in FIG. 6A, showing only a sectional structure view in the Y direction where the semi-floating gate trenches 103 are formed.

Referring to FIG. 6A, both a storage unit area 101a and a logic area 101b are included in the semiconductor substrate 101, and in FIG. 6A, the storage unit area 101a and the logic area 101b are separated by a line AA. The storage unit is formed in the storage unit area 101a and a logic device is formed in the logic area 101b.

In the method of the embodiment of the present application, referring to FIG. 6C, the Y-direction trench patterned etching also simultaneously etches the first field oxides 102 at both sides of the semi-floating gate trenches 103 and forms second trenches 103a. FIG. 6C shows the top surfaces of the first field oxides 102 are located at a dashed line EE.

Referring to FIG. 6D, the semi-floating gate trenches 103 and the second trenches 103a at both sides are communicated together and aligned along sides in the Y-direction; and bottom surfaces of the second trenches 103a are higher than bottom surfaces of the semi-floating gate trenches 103.

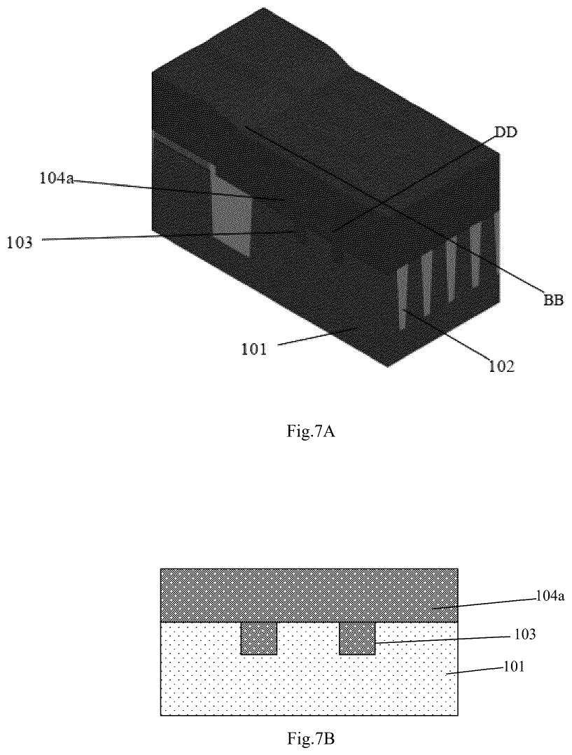

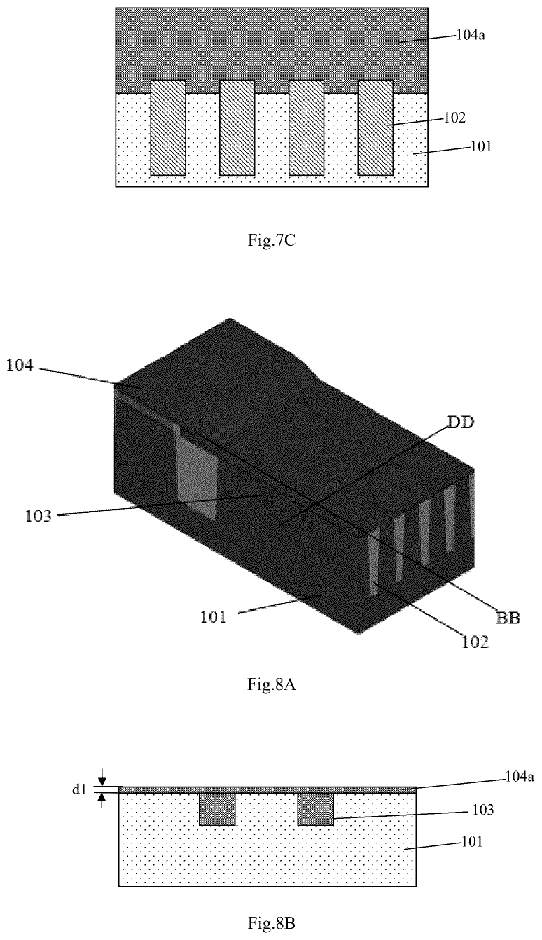

The method comprises step S103 of, referring to FIG. 7A, sequentially forming semi-floating gate dielectric layers and semi-floating gate conductive material layers 104a, the semi-floating gate dielectric layers being formed on the inner surfaces of the semi-floating gate trenches 103, and the semi-floating gate dielectric layers also extending to the surfaces of the first active areas outside the semi-floating gate trenches 103 and being formed with semi-floating gate dielectric windows; and the semi-floating gate conductive material layers 104a being filled in the semi-floating gate trenches and extending outside the semi-floating gate trenches 103, and at the semi-floating gate dielectric windows, the semi-floating gate conductive material layers 104a contacting with the surfaces of the first active areas.

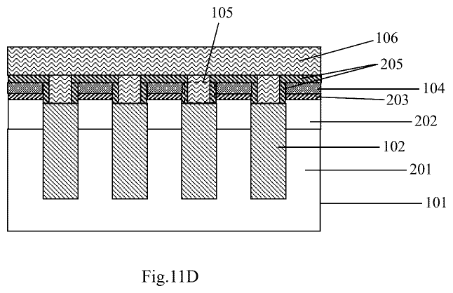

FIG. 7A is a three-dimensional view, please refer to FIG. 7B and FIG. 7C for a clearer structure, FIG. 7B is a sectional view along a line BB in FIG. 7A, and FIG. 7C is a sectional view along a line DD in FIG. 7A. In FIG. 7B, the semi-floating gate dielectric layers and the semi-floating gate dielectric windows are omitted, and for the structure of the semi-floating gate dielectric layers, please refer to the semi-floating gate dielectric layers 203 in FIG. 11B; and for the structure of the semi-floating gate dielectric windows, please refer to the semi-floating gate dielectric windows 204 in FIG. 11B.

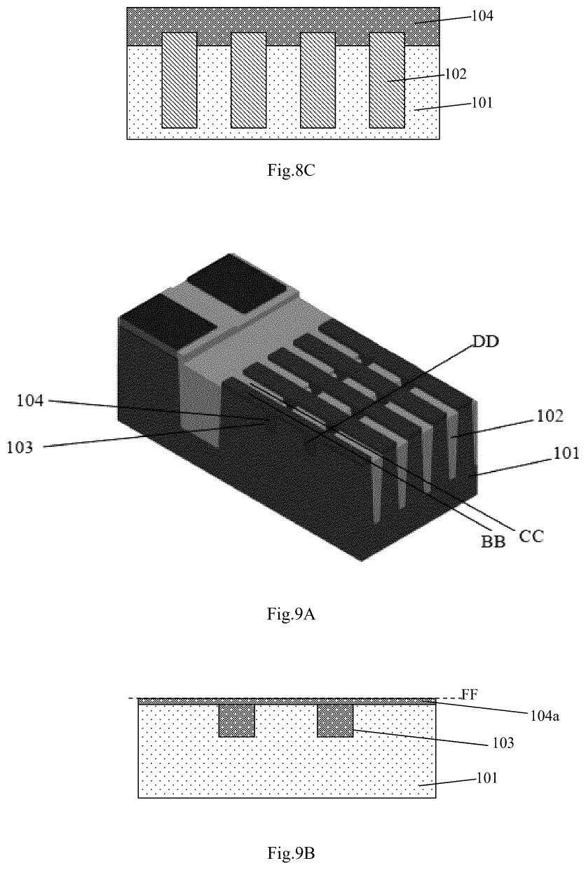

In the method of the embodiment of the present application, referring to FIG. 8A, further comprised is performing blanket etch for the semi-floating gate conductive material layers 104a, to thin thicknesses of the semi-floating gate conductive material layers 104a, and in FIG. 8A, the semi-floating gate conductive material layers after thinning are the semi-floating gate conductive material layers 104.

FIG. 8A is a three-dimensional view, please refer to FIG. 8B and FIG. 8C for a clearer structure, FIG. 8B is a sectional view along a line BB in FIG. 8A, and FIG. 8C is a sectional view along a line DD in FIG. 8A.

In the method of some embodiments, the semi-floating gate conductive material layers 104a extending outside the semi-floating gate trenches 103 have a thickness d1 with a minimum value less than 110 Å.

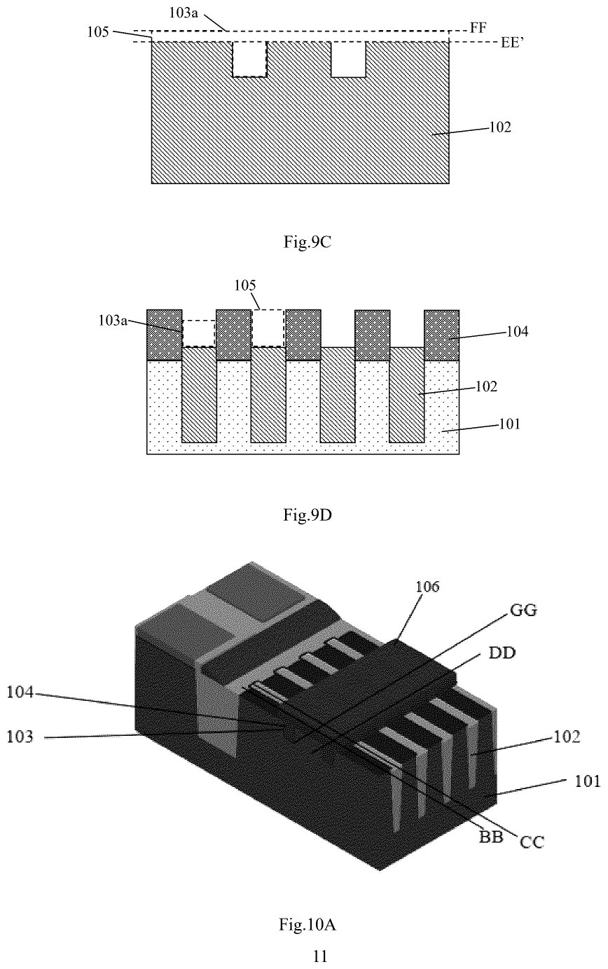

The method comprises step S104 of, referring to FIG. 9A, performing X-direction trench patterned etching to remove the semi-floating gate conductive material layers 104 of tops of the first field oxides 102 and form semi-floating gate split trenches 105, the semi-floating gate split trenches 105 fully isolating, by cutting, the semi-floating gate conductive material layers 104 at both sides, and first sides and second sides of the semi-floating gate conductive material layers 104 being exposed to sides of the semi-floating gate split trenches 105 at both sides; and the sides of the semi-floating gate split trenches 105 extending in the X direction and being defined by a photomask.

The X-direction trench patterned etching is U-trench X etching, and a trench pattern extends in the X-direction.

FIG. 9A is a three-dimensional view, please refer to FIGS. 9B to 9C for a clearer structure, FIG. 9B is a sectional view along a line BB in FIG. 9A, FIG. 9C is a sectional view along line CC in FIG. 9A, and FIG. 9D is a sectional view along line DD in FIG. 9A.

FIG. 9B is a section along an extension direction of first active areas, the X-direction trench patterned etching does not etch the first active areas, so that FIG. 9B and FIG. 8B have the same structure. FIG. 9B shows that the top surfaces of the semi-floating gate conductive material layers 104 are located at a dashed line FF.

Line CC is an etched area of the X-direction trench patterned etching, and by the etching shown in FIG. 9C, the X-direction trench patterned etching causes that a position outside the second trenches 103a decreases from the dashed line FF to a dashed line EE′, which removes the semi-floating gate conductive material layers 104 between the dashed lines FF and EE′ and in the second trenches 103a and thereby forms the semi-floating gate split trenches 105. The second trenches 103a are a part of the semi-floating gate split trenches 105. The second trenches 103a are constituent portions of the semi-floating gate split trenches 105, and the bottom surfaces of the semi-floating gate split trenches 105 at the second trenches 103a are lower than the bottom surfaces outside the second trenches 103a. All the semi-floating gate split trenches 105 shown in FIG. 9D comprise the second trenches 103a.

In the method of some embodiments, the X-direction trench patterned etching also removes partial thicknesses of the first field oxides 102 after etching away the semi-floating gate conductive material layers 104, so that the bottom surfaces of the semi-floating gate split trenches 105 are lower than the top surfaces of the shallow trenches; at this point, the position of the dashed EE′ in FIG. 9C is lower than the position of the dashed EE in FIG. 6C, and the dashed line EE′ is the top surface of the first field oxide 102 after the X-direction trench patterned etching is completed, and also the bottom surface of the semi-floating gate split trench 105 outside the second trench 103a; and the dashed line EE is the top surface of the first field oxide 102 prior to the X-direction trench patterned etching, and also the top surface of the shallow trench.

In the method of some embodiments, it can also be that the position of the dashed EE′ is the same as that of the dashed EE in FIG. 6C, and in such a case, there is no thickness loss of the first field oxides 102 in the X-direction trench patterned etching.

Referring to FIG. 9D, the X-direction trench patterned etching can ensure that the semi-floating gate conductive material layers 104 at both sides of the semi-floating gate split trenches 105 are isolated from each other, thereby solving the defect in the existing method that the half-leaf gate conductive material layers 104 at both sides of the field oxides 302, referring to FIG. 4B, are likely to contact with each other at the tops of the hard mask layers 303a of the field oxides 302.

In the method of the embodiment of the present application, in the X-direction trench patterned etching, a photomask defining the shallow trench is used to define an area for forming the semi-floating gate split trenches 105.

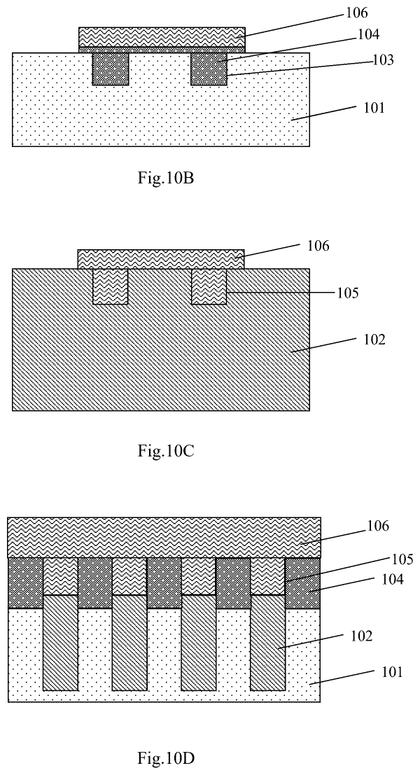

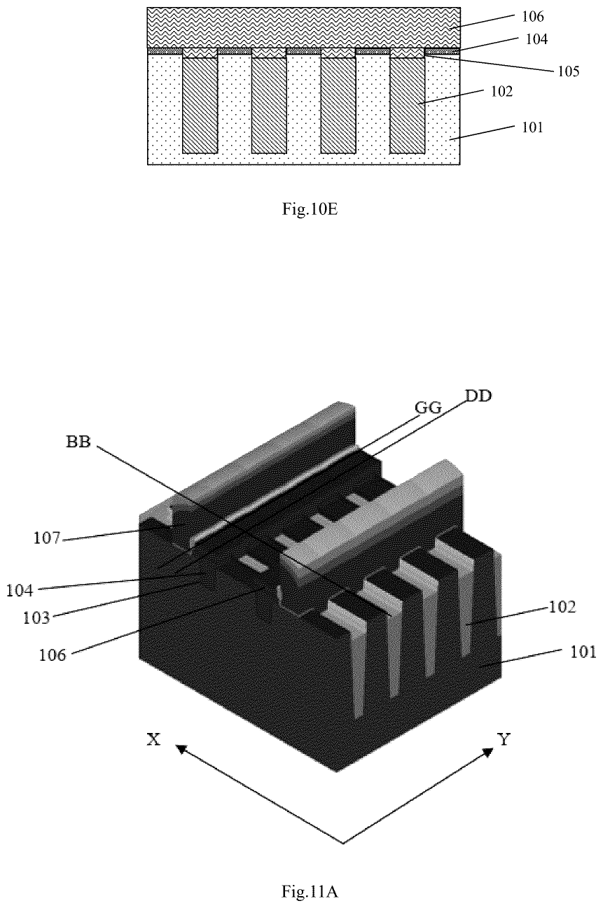

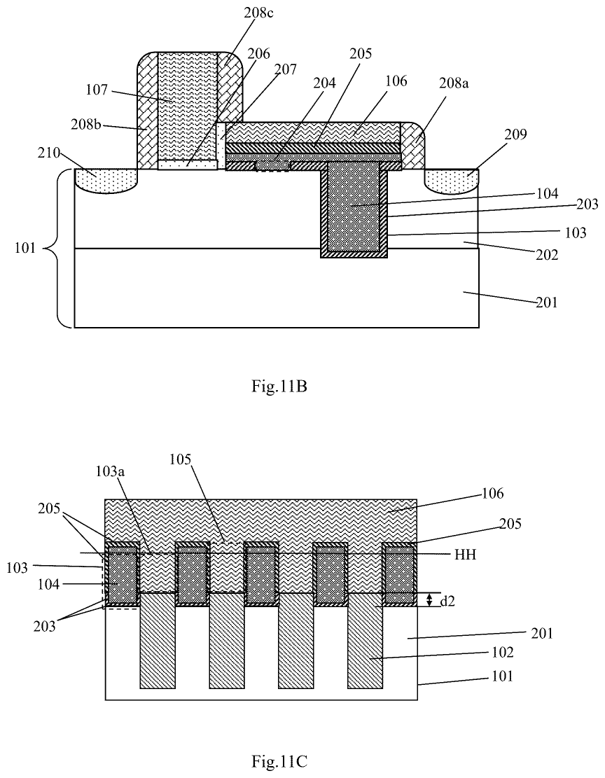

The method comprises step S105 of, referring to FIG. 10A, sequentially forming control gate dielectric layers and control gate conductive material layers 106 on the first sides and second sides, and top surfaces of the semi-floating gate conductive material layers 104, the control gate conductive material layers 106 wrapping the semi-floating gate conductive material layers 104 from the first sides and second sides, and top surfaces of the semi-floating gate conductive material layers 104, and the control gate conductive material layers 106 also completely filling the semi-floating gate split trenches 105 at both sides of the wrapped semi-floating gate conductive material layers 104; and

performing control gate patterned etching, the control gate patterned etching comprising etching the control gate conductive material layers 106 to form first sides and second sides of the control gate conductive material layers 106 extending in the Y direction, and etching the semi-floating gate conductive material layers 104 to form third sides and fourth sides of the semi-floating gate conductive material layers 104, the third sides of the semi-floating gate conductive material layers 104 and the first sides of the control gate conductive material layers 106 being aligned vertically, and the fourth sides of the semi-floating gate conductive material layers 104 and the second sides of the control gate conductive material layers 106 being aligned vertically.

FIG. 10A shows a three-dimensional view after the control gate patterned etching is completed. For a clearer structure, please refer to FIGS. 10B to 10E, FIG. 10B is a sectional view along a line BB in FIG. 10A, FIG. 10C is a sectional view along a line CC in FIG. 10A, and FIG. 10D is a sectional view along a line DD in FIG. 10A; and FIG. 10E is a sectional view along a line GG in FIG. 10A, the line GG corresponding to a straight line in the Y-direction outside the semi-floating gate trenches 103.

Referring to FIG. 10A, after the control gate patterned etching is completed, the control gate conductive material layers 106 of the storage units aligned in the Y-direction are connected together to form a first conductive material strip structure.

For the control gate dielectric layers omitted in FIG. 10B, reference can be made to the control gate dielectric layers 205 in FIG. 11B.

FIG. 10C shows the semi-floating gate split trenches 105 comprising the second trenches 103a, and it can be seen that the control gate conductive material layers 106, in addition to covering the semi-floating gate conductive material layers 104 from the top surfaces of the semi-floating gate conductive material layers 104, also cover the semi-floating gate conductive material layers 104 from the first sides and second sides of the semi-floating gate conductive material layers 104 exposed in the semi-floating gate split trenches 105; and the area of the control gate conductive material layers 106 covering the semi-floating gate conductive material layers 104 is increased, i.e., the coupling area of the two is increased, so that more storage charge can be injected into the semi-floating gate conductive material layers 104 during programming of the storage unit, i.e., writing of “1”, so that a “1”-state is more stable, a threshold voltage change is larger, and the reading-“1” performance can also be increased.

The method of the embodiment of the present application further comprises:

step S106 of, referring to FIG. 11B, forming a selection gate dielectric layer 206, a first inter-gate dielectric layer 207, and a selection gate conductive material layer 107; the selection gate conductive material layer 107 is formed on a top of the first active area 209 outside the second sides of the control gate conductive material layers 106, a first side of the selection gate conductive material layer 107 is isolated from the second sides of the control gate conductive material layers 106 and the fourth sides of the semi-floating gate conductive material layers 104 by the first inter-gate dielectric layer 207.

FIG. 11A shows a three-dimensional view after the selection gate conductive material layer 107 is formed, and FIG. 11B is a sectional structural view of one storage unit along a center line BB of FIG. 11A.

The selection gate conductive material layer 107 is isolated from the top surface of the first active area 209 by the selection gate dielectric layer 206.

In the method of the embodiment of the present application, a material of the semiconductor substrate 101 comprises silicon.

A material of the semi-floating gate conductive material layers 104 comprises polysilicon.

A material of the control gate conductive material layers 106 comprises polysilicon.

A material of the selection gate conductive material layer 107 comprises polysilicon.

In the method of other embodiments, the material of the semi-floating gate conductive material layers 104 can also include metal; the material of the control gate conductive material layers 106 can also include metal; and the material of the selection gate conductive material layer 107 can also include metal.

In the provided semiconductor substrate 101, a lightly doped source-drain area 202 with a first conductive type is formed in a surface area of the first active area 209 and a doped channel area 201 with a second conductive type located at a bottom of the lightly doped source-drain area 202.

The semi-floating gate trenches 103 pass through the lightly doped source-drain area 202 and bottom surfaces of the semi-floating gate trenches 103 enter the channel area 201.

Further comprised is a step of:
forming first sidewalls 208a on the first sides of the control gate conductive material layers 106 and third sides of the semi-floating gate conductive material layers 104, and forming second sidewalls 208b on second sides of the selection gate conductive material layer 107. In FIG. 11B, the height of the selection gate conductive material layer 107 is higher than the top surface of the control gate conductive material layer 106, and therefore, third sidewalls 208c are formed on the first side of the selection gate conductive material layer 107. The first sidewalls 208a, second sidewalls 208b and third sidewalls 208c can be formed simultaneously using the same process. In the method of some embodiments, it can also be that the selection gate conductive material layer 107 also extend overtop surfaces of the control gate conductive material layers 106.

Heavily doped source-drain implantation with a first conductive type is performed for self-alignment in the lightly doped source-drain area 202 outside the first sidewalls 208a to form a source area 209 and self-alignment in the lightly doped source-drain area 202 outside the second sidewalls 208bb to form a drain area 210.

FIG. 11C shows a sectional structural view along a line DD in FIG. 11A, the semi-floating gate trenches 103 are located at the line DD, FIG. 11D is a sectional structural view along a line GG in FIG. 11A, and the line GG is located outside the semi-floating gate trenches 103.

The structure at FIG. 11C is the same as that at FIG. 10D, but FIG. 11C further shows the structures of the semi-floating gate dielectric layer 203, control gate dielectric layer 205, and channel area 201.

The structure at FIG. 11D is the same as that at FIG. 10E, but FIG. 11C further shows the structures of the semi-floating gate dielectric layer 203, control gate dielectric layer 205, channel area 201, and lightly doped source-drain area 202.

Referring to FIG. 11C, the minimum spacing between the control gate conductive material layer 106 and the channel area 201 is a distance d2. The distance d2 is a distance between the bottom surface of the control gate conductive material layer 106 located in the semi-floating gate trench 103 and the top surface of the channel area 201. However, in FIG. 5B corresponding to the existing method, the minimum spacing between the control gate conductive material layer 307 and the channel area at the bottom is distance d102, the distance d102 is the spacing between the control gate conductive material layer 307 on the top surface of the semi-floating gate conductive material layer 306 and the channel area at the bottom, and it can be seen that the distance d2 is less than the distance d102, and therefore, the method of the embodiment of the present application can reduce the minimum spacing between the control gate conductive material layer 106 and the channel area 201, which can increase the ability for controlling the channel area 201 by the control gate conductive material layers 106.

In the prior art, a semi-floating gate conductive material layer 104 is formed on a surface of a semiconductor substrate 101 after completion of X- and Y-direction trench patterned etching, the X-direction trench patterned etching causes a top surface of an active area 209, i.e., a first active area 209, in a storage unit area 101a to be lower than a top surface of a hard mask layer at a top of a first field oxide 102, and after the semi-floating gate conductive material layer 104 is filled, the difference between a top surface of the semi-floating gate conductive material layer 104 and the top surface of the hard mask layer at the top of the first field oxide 102 is adjusted by performing maskless-defined blanket etch on the semi-floating gate conductive material layer 104. If the top surface of the semi-floating gate conductive material layer 104 is higher than the top surface of the hard mask layer at the top of the first field oxide 102, the top surface of the hard mask layer at the top of the first field oxide 102 has a remained semi-floating gate conductive material layer, and the semi-floating gate conductive material layers 104 in two adjacent first active area-heavy layers 209 are connected together at the top of the hard mask layer at the top of the first field oxide 102; and therefore, a process window for controlling isolation between the semi-floating gate conductive material layers 104 in two adjacent first active areas 209 by blanket etch of the semi-floating gate conductive material layer 104 is relatively small, with a poor process stability.

However, in the method of the embodiment of the present application, the semi-floating gate conductive material layers 104 are directly formed in the semi-floating gate trenches 103 and extend outside the semi-floating gate trenches 103, and X-direction patterns of the semi-floating gate conductive material layers 104, i.e., the first sides and the second sides, are defined by the sides of the semi-floating gate split trenches 105 formed at the tops of the first field oxides 102; and since the semi-floating gate split trenches 105 themselves are trenches formed by splitting the semi-floating gate conductive material layers 104, the semi-floating gate split trenches 105 can fully isolate, by cutting, the semi-floating gate conductive material layers 104 at both sides, and it can be ensured that semi-floating gate conductive material layers 104 on two adjacent first active areas 209 are not connected together; and the semi-floating gate split trenches 105 only need to fully isolate, by cutting, the semi-floating gate conductive material layers 104, and are not limited by the thickness of the semi-floating gate conductive material layer 104 of the surface of the first active area 209 and the thickness of the hard mask layer of the top of the first field oxide 102, so the method of the embodiment of present application can increase a process window, and reduce process control difficulty.

The semi-floating gate split trenches 105 provided by the method of the embodiment of the present application can expose the first sides and second sides of the semi-floating gate conductive material layers 104 while splitting the semi-floating gate conductive material layers 104, and the control gate conductive material layers 106 of the method of the embodiment of the present application further cover on the first sides and second sides of the semi-floating gate conductive material layers 104, so that the control gate conductive material layers 106 can wrap the semi-floating gate conductive material layers 104 from the first sides and second sides, and top surfaces of the semi-floating gate conductive material layers 104; and compared with the existing method in which the control gate conductive material layers 106 can cover the semi-floating gate conductive material layers 104 only from the top surfaces of the semi-floating gate conductive material layers 104, the present application increases the area of the control gate conductive material layers 106 covering the semi-floating gate conductive material layers 104, i.e., the coupling area between the control gate conductive material layers 106 and the semi-floating gate conductive material layers 104 increases, so, during writing, i.e. programming, the amount of charge written to the semi-floating gate conductive material layers 104 increases, thereby increasing read-“1” performance of a device.

In addition, after the control gate conductive material layers 106 of the method of the embodiment of the present application cover the semi-floating gate conductive material layers 104 from the sides, the minimum distance between the control gate conductive material layers 106 and the channel areas 201 is the distance between the lowest position of the control gate conductive material layers 106 located at the sides of the semi-floating gate conductive material layers 104 and the channel areas 201, and that distance is smaller than the distance between the lowest position of the control gate conductive material layers 106 located at the top surfaces of the semi-floating gate conductive material layers 104 and the channel areas 201, and thus, a voltage drop from the control gate conductive material layers 106 to the channel areas 201 can be reduced, thereby being capable of increasing an effective voltage applied on the channel areas 201.

The semi-floating gate transistor of the embodiment of the present application comprises:
referring to FIG. 11A, a plurality of storage units formed in a storage unit area 101a. For the relative position of the storage unit area 101a and logic area 101b, please refer to FIG. 6A.

In the storage unit area 101a, first active areas 209 defined by first field oxides 102 are formed on the semiconductor substrate 101, the first active areas 209 are arranged in parallel, and the first field oxides 102 are arranged in parallel.

An extension direction of the first active areas 209 is an X-direction, and a direction in which the first active areas 209 are arranged alternately with the first field oxides 102 is a Y-direction.

FIG. 11B shows a sectional structural view of a storage unit along a line BB in FIG. 11A. The storage unit comprises semi-floating gate trenches 103 formed in a selected area of the first active area 209.

Semi-floating gate dielectric layers 203 are formed at inner surfaces of the semi-floating gate trenches 103, the semi-floating gate dielectric layers 203 further extending to surfaces of the first active areas 209 outside the semi-floating gate trenches 103 and being formed with semi-floating gate dielectric windows 204.

Semi-floating gate conductive material layers 104 are filled in the semi-floating gate trenches 103 and extend outside the semi-floating gate trenches 103, and at the semi-floating gate dielectric windows 204, the semi-floating gate conductive material layers 104 contact with surfaces of the first active areas 209.

In the embodiment of the present application, the semi-floating gate conductive material layers 104 extending outside the semi-floating gate trenches 103 have a thickness with a minimum value less than 110 Å. The thickness of the semi-floating gate conductive material layers 104 extending outside of the semi-floating gate trenches 103 is obtained by blanket etching of the semi-floating gate conductive material layers 104.

FIG. 11C is a sectional structural view of a storage unit along a line DD in FIG. 11A. The semi-floating gate split trenches 105 are formed at the tops of the first field oxides 102, and the semi-floating gate split trenches 105 fully isolate, by cutting, the semi-floating gate conductive material layers 104 at both sides, and first sides and second sides of the semi-floating gate conductive material layers 104 are exposed to sides of the semi-floating gate split trenches 105 at both sides.

Control gate dielectric layers 205 and control gate conductive material layers 106 are formed at the first sides and second sides, and top surfaces of the semi-floating gate conductive material layers 104, the control gate conductive material layers 106 wrap the semi-floating gate conductive material layers 104 from the first sides and second sides, and top surfaces of the semi-floating gate conductive material layers 104, and the control gate conductive material layers 106 also completely fill the semi-floating gate split trenches 105 at both sides of the wrapped semi-floating gate conductive material layers 104.

The control gate conductive material layers 106 have first sides and second sides extending in the Y direction.

Referring to FIG. 11A, the control gate conductive material layers 106 of the storage units aligned in the Y direction are connected together to form a first conductive material strip structure.

Referring to FIG. 11B, third sides of the semi-floating gate conductive material layers 104 and the first sides of the control gate conductive material layers 106 are aligned vertically, and fourth sides of the semi-floating gate conductive material layers 104 and the second sides of the control gate conductive material layers 106 are aligned vertically.

Referring to FIG. 11C, second trenches 103a are also formed in both sides of the semi-floating gate trenches 103, the semi-floating gate trenches 103 and the second trenches 103a in both sides are communicated together and aligned along sides in the Y-direction; and the second trenches 103a are recessed in the first field oxides 102, and bottom surfaces of the second trenches 103a are higher than bottom surfaces of the semi-floating gate trenches 103. In FIG. 11C, a line HH corresponds to positions of top surfaces of the first active areas, the semi-floating gate conductive material layers 104, after they completely fill the semi-floating gate trenches 103, also extend over the top surfaces of the first active areas, so that the top surfaces of the semi-floating gate conductive material layers 104 are higher than the top surfaces of the semi-floating gate trenches 103, i.e., the top surfaces of the first active areas, i.e., the surfaces corresponding to the line HH.

The semi-floating gate split trenches 105 in FIG. 11C comprise the second trenches 103a.

FIG. 11D is located outside the semi-floating gate trenches 103, so that the second trenches 103a are not formed, the semi-floating gate split trenches 105 in FIG. 11D does not comprise the second trenches 103a, so that the semi-floating gate split trenches 105 in FIG. 11D are shallower, i.e., the second trenches 103a are constituent portions of the semi-floating gate split trenches 105, and the bottom surfaces of the semi-floating gate split trenches 105 at the second trenches 103a are lower than the bottom surfaces outside the second trenches 103a.

In the embodiment of the present application, the first field oxides 102 use shallow trench isolation filled with a shallow trench.

In some embodiments, referring to FIG. 11D, bottom areas of the semi-floating gate split trenches 105 further comprise partial thicknesses of removing areas of the first field oxides 102, and bottom surfaces of the semi-floating gate split trenches 105 outside the second trenches 103a are lower than the top surfaces of the shallow trenches. In some embodiments, it can also be that the first field oxides 102 of the bottom areas of the semi-floating fence split trenches 105 are not subjected to thickness depletion, and the bottom surfaces of the semi-floating fence split trenches 105 outside the second trenches 103a are equal to the top surfaces of the shallow trenches.

Referring to FIG. 11B, the selection gate conductive material layer 107 is formed on a top of the first active area 209 outside the second sides of the control gate conductive material layers 106, a first side of the selection gate conductive material layer 107 is isolated from the second sides of the control gate conductive material layers 106 and the fourth sides of the semi-floating gate conductive material layers 104 by the first inter-gate dielectric layer 207.

The selection gate conductive material layer 107 is isolated from the top surface of the first active area 209 by a selection gate dielectric layer 206.

Also included is:
a lightly doped source-drain area 202 with a first conductive type formed in a surface area of the first active area 209 and a doped channel area 201 with a second conductive type located at a bottom of the lightly doped source-drain area 202.

The semi-floating gate trenches 103 pass through the lightly doped source-drain area 202 and bottom surfaces of the semi-floating gate trenches 103 enter the channel area 201.

First sidewalls 208a are formed on the first sides of the control gate conductive material layers 106 and the third sides of the semi-floating gate conductive material layers 104, a heavily doped source area 209 with a first conductive type is formed in the lightly doped source-drain area 202 outside the first sidewalls 208a, and the source area 209 and sides of the first sidewalls 208a are self-aligned.

A second sidewall 208b is formed on a second side of the selection gate conductive material layer 107, a heavily doped drain area 210 with a first conductive type is formed in the lightly doped source-drain area 202 outside the second sidewall 208b, and the drain area 210 and a side of the second sidewall 208b are self-aligned.

In FIG. 11B, the height of the selection gate conductive material layer 107 is higher than the top surface of the control gate conductive material layer 106, and therefore, third sidewalls 208c are formed on the first side of the selection gate conductive material layer 107. The first sidewall 208a, second sidewall 208b and third sidewall 208c can be formed simultaneously using the same process. In the method of some embodiments, it can also be the case that the selection gate conductive material layer 107 also extend over top surfaces of the control gate conductive material layers 106.

In the embodiment of the present application, a material of the semiconductor substrate 101 comprises silicon.

A material of the semi-floating gate conductive material layers 104 comprises polysilicon.

A material of the control gate conductive material layers 106 comprises polysilicon.

A material of the selection gate conductive material layer 107 comprises polysilicon.

In other embodiments, the material of the semi-floating gate conductive material layers 104 can also comprise metal; the material of the control gate conductive material layers 106 can also comprise metal; and the material of the selection gate conductive material layer 107 can also comprise metal.

Compared with the existing method, the method of the embodiment of the present application performs polysilicon X-direction cut (Poly X CUT) in an STI area, i.e. the areas of the first field oxides 102, by enabling the U-trench X etching after the U-trench Y etching, that is, the method realizes cut of the semi-floating gate conductive material layers 104 in the STI area by the U-trench X etching.

The U-trench X etching is to etch semi-floating gate poly in the STI area by utilizing an STI Poly cut process, i.e., the semi-floating gate conductive material layers 104, after the semi-floating gate poly blanket ET. In the method of some typical embodiments, the U-trench X etching can achieve etching area definition by reverse tune using a mask for the U-trench X etching in the existing method and performing a positive-photoresist negative-tone-development process. In the method of the present application, on the one hand, the semi-floating gate poly can be isolated from each other, fundamentally avoiding the risk that semi-floating gate poly is still shorted after poly blanket ET in the prior art; and on the other hand, the method of the embodiment of the present application can additionally expose two sides of the semi-floating gate poly, thereby forming a three-sided surrounded control poly gate from the top and the sides after dep control poly.

The method of the embodiment of the present application can well isolate a semi-floating gate poly gate, avoiding its short circuit to increase a process window.

In the existing method, effective isolation of the semi-floating gate poly gate requires that an effective amount of HM remaining in an STI area after U-trench Y etching is greater than a remaining amount after semi-floating gate poly gate etching, such as 110 Å. Since the U-trench Y enables loss of STI HM, posing challenges on a process stability and a window for the U-trench Y etching and semi-floating gate poly gate dep and etching.

In the method of the embodiment of the present application, the semi-floating gate poly gate is directly cut off using an STI poly cut process, and the semi-floating gate poly gate is isolated using the control gate dielectric layer 205 and the control poly gate, i.e., the control gate conductive material layer 106, with a stable reliable process.

The method of the embodiment of the present application can also increase the coupling area of the semi-floating gate poly gate and control poly gate to improve the read-“1” performance of a device.

In the prior art, an effective coupling area of a control poly gate and a semi-floating gate poly gate is only at a top of the semi-floating gate poly gate.

In the method of the embodiment of the present application, when the STI poly cut cuts the semi-floating gate poly gate, on the one hand, two sides of the semi-floating gate poly gate are exposed, and after they contact with the control poly gate, a three-sided surrounded gate structure is formed, being capable of increasing an effective coupling area by about 66%, and more electric charge can be adsorbed during charging, thereby improving read-“1” performance of a device; and on the other hand, the distance between the control poly gate and the U-trench channel is reduced by about 50%, i.e., being reduced from d102 in FIG. 5B to d2 in FIG. 11C, being capable of reducing a voltage drop from a control gate to a U-trench channel to increase an effective voltage drop applied on a channel.

The present application is described in detail above by specific embodiments, but these are not intended to limit the present application. Many deformations and improvements which may be further made by those skilled in the art without departing from the principle of the present application should also be included within the scope of protection of the present application.

What is claimed is:

1. A semi-floating gate transistor, wherein the semi-floating gate transistor comprises a plurality of storage units formed in a storage unit area;
in the storage unit area, first active areas defined by first field oxides are formed on a semiconductor substrate, the first active areas are arranged in parallel, and the first field oxides are arranged in parallel;
an extension direction of the first active areas is an X direction, and a direction in which the first active areas are arranged alternately with the first field oxides is a Y direction;
the storage units comprise semi-floating gate trenches formed in selected areas of the first active areas;
semi-floating gate dielectric layers are formed at inner surfaces of the semi-floating gate trenches, the semi-floating gate dielectric layers further extending to surfaces of the first active areas outside the semi-floating gate trenches and being formed with semi-floating gate dielectric windows;
semi-floating gate conductive material layers are filled in the semi-floating gate trenches and extend outside the semi-floating gate trenches, and at the semi-floating gate dielectric windows, the semi-floating gate conductive material layers contact with surfaces of the first active areas;
semi-floating gate split trenches are formed in tops of the first field oxides, the semi-floating gate split trenches fully isolate, by cutting, the semi-floating gate conductive material layers at both sides, and first sides and second sides of the semi-floating gate conductive material layers are exposed to sides of the semi-floating gate split trenches at both sides;
control gate dielectric layers and control gate conductive material layers are formed at the first sides and second sides, and top surfaces of the semi-floating gate conductive material layers, the control gate conductive material layers wrapping the semi-floating gate conductive material layers from the first sides and second sides, and top surfaces of the semi-floating gate conductive material layers, and the control gate conductive material layers also completely filling the semi-floating gate split trenches at both sides of the wrapped semi-floating gate conductive material layers;
the control gate conductive material layers have first sides and second sides extending in the Y direction; and
third sides of the semi-floating gate conductive material layers and the first sides of the control gate conductive material layers are aligned vertically, and fourth sides of the semi-floating gate conductive material layers and the second sides of the control gate conductive material layers are aligned vertically.

2. The semi-floating gate transistor according to claim 1, wherein second trenches are also formed in both sides of the semi-floating gate trenches, the semi-floating gate trenches and the second trenches in both sides are communicated together and aligned along sides in the Y direction; and the second trenches are recessed in the first field oxides, and bottom surfaces of the second trenches are higher than bottom surfaces of the semi-floating gate trenches.

3. The semi-floating gate transistor according to claim 2, wherein the first field oxides use shallow trench isolation filled in a shallow trench;
bottom areas of the semi-floating gate split trenches further comprise partial thicknesses of removing areas of the first field oxides, and bottom surfaces of the semi-floating gate split trenches are lower than the top surfaces of the shallow trenches; and
the second trenches are constituent portions of the semi-floating gate split trenches, and the bottom surfaces of the semi-floating gate split trenches at the second trenches are lower than the bottom surfaces outside the second trenches.

4. The semi-floating gate transistor according to claim 1, wherein a selection gate conductive material layer is formed at a top of the first active area outside the second sides of the control gate conductive material layers, a first side of the selection gate conductive material layer is isolated from the second sides of the control gate conductive material layers and the fourth sides of the semi-floating gate conductive material layers by a first inter-gate dielectric layer; and
the selection gate conductive material layer is isolated from the top surface of the first active area by a selection gate dielectric layer.

5. The semi-floating gate transistor according to claim 4, further comprising:
a lightly doped source-drain area with a first conductive type formed in a surface area of the first active area and a doped channel area with a second conductive type located at a bottom of the lightly doped source-drain area;
the semi-floating gate trenches pass through the lightly doped source-drain area and bottom surfaces of the semi-floating gate trenches enter the channel area;
first sidewalls are formed on the first sides of the control gate conductive material layers and the third sides of the semi-floating gate conductive material layers, a source area heavily doped with the first conductive type is formed in the lightly doped source-drain area outside the first sidewalls, and the source area and sides of the first sidewalls are self-aligned; and
a second sidewall is formed on a second side of the selection gate conductive material layer, a drain area heavily doped with the first conductive type is formed in the lightly doped source-drain area outside the second sidewall, and the drain area and a side of the second sidewall are self-aligned.

6. The semi-floating gate transistor according to claim 1, wherein the control gate conductive material layers of the storage units aligned in the Y direction are connected together to form a first conductive material strip structure.

7. The semi-floating gate transistor according to claim 1, wherein the semi-floating gate conductive material layers extending outside the semi-floating gate trenches have a thickness with a minimum value less than 110 Å.

8. The semi-floating gate transistor according to claim 4, wherein a material of the semiconductor substrate comprises silicon;
a material of the semi-floating gate conductive material layers comprises polysilicon;
a material of the control gate conductive material layers comprises polysilicon; and
a material of the selection gate conductive material layer comprises polysilicon.

9. A method of manufacturing a semi-floating gate transistor, comprising:
providing a semiconductor substrate in which, in a storage unit area, first active areas defined by first field oxides are formed on the semiconductor substrate, the first active areas being arranged in parallel, and the first field oxides being arranged in parallel; and an extension direction of the first active areas being an X direction, and a direction in which the first active areas are arranged alternately with the first field oxides being a Y direction;
performing Y direction trench patterned etching to form semi-floating gate trenches in selected areas of the first active areas, the semi-floating gate trenches having first sides and second sides extending in the X direction, and third sides and fourth sides extending in the Y direction; and the third sides and fourth sides of the semi-floating gate trenches being defined by a photomask, and the first sides and second sides of the semi-floating gate trenches being defined by self-alignment of the first field oxides at both sides;
sequentially forming semi-floating gate dielectric layers and semi-floating gate conductive material layers, the semi-floating gate dielectric layers being formed on inner surfaces of the semi-floating gate trenches, and the semi-floating gate dielectric layers also extending to surfaces of the first active areas outside the semi-floating gate trenches and being formed with semi-floating gate dielectric windows; and the semi-floating gate conductive material layers being filled in the semi-floating gate trenches and extending outside the semi-floating gate trenches, and at the semi-floating gate dielectric windows, the semi-floating gate conductive material layers contacting with the surfaces of the first active areas;
performing X direction trench patterned etching to remove the semi-floating gate conductive material layers of tops of the first field oxides and form semi-floating gate split trenches, the semi-floating gate split trenches fully isolating, by cutting, the semi-floating gate conductive material layers at both sides, and first sides and second sides of the semi-floating gate conductive material layers being exposed to sides of the semi-floating gate split trenches at both sides; and the sides of the semi-floating gate split trenches extending in the X direction and being defined by a photomask;
forming control gate dielectric layers and control gate conductive material layers on the first sides and second sides, and top surfaces of the semi-floating gate conductive material layers, the control gate conductive material layers wrapping the semi-floating gate conductive material layers from the first sides and second sides, and top surfaces of the semi-floating gate conductive material layers, and the control gate conductive material layers also completely filling the semi-floating gate split trenches at both sides of the wrapped semi-floating gate conductive material layers; and
performing control gate patterned etching, the control gate patterned etching comprising etching the control gate conductive material layers to form first sides and second sides of the control gate conductive material layers extending in the Y direction, and etching the semi-floating gate conductive material layers to form third sides and fourth sides of the semi-floating gate conductive material layers, the third sides of the semi-floating gate conductive material layers and the first sides of the control gate conductive material layers being aligned vertically, and the fourth sides of the semi-floating gate conductive material layers and the second sides of the control gate conductive material layers being aligned vertically.

10. The method of manufacturing the semi-floating gate transistor according to claim 9, wherein the Y direction trench patterned etching also simultaneously etches the first field oxides at both sides of the semi-floating gate trenches and forms second trenches, the semi-floating gate trenches and the second trenches at both sides are communicated together and aligned along sides in the Y direction; and bottom surfaces of the second trenches are higher than bottom surfaces of the semi-floating gate trenches.

11. The method of manufacturing the semi-floating gate transistor according to claim 10, wherein the first field oxides use shallow trench isolation filled in a shallow trench;
the X direction trench patterned etching also removes partial thicknesses of the first field oxides after etching away the semi-floating gate conductive material layers, so that the bottom surfaces of the semi-floating gate split trenches are lower than the top surfaces of the shallow trenches; and
the second trenches are constituent portions of the semi-floating gate split trenches, and the bottom surfaces of the semi-floating gate split trenches at the second trenches are lower than the bottom surfaces outside the second trenches.

12. The method of manufacturing the semi-floating gate transistor according to claim 11, wherein in the X direction trench patterned etching, a photomask defining the shallow trench is used to define an area for forming the semi-floating gate split trenches.

13. The method of manufacturing the semi-floating gate transistor according to claim 9, further comprising:
forming a selection gate dielectric layer, a first inter-gate dielectric layer, and a selection gate conductive material layer; the selection gate conductive material layer being formed at tops of the first active areas outside the second sides of the control gate conductive material layers, and first side of the selection gate conductive material layer being isolated from second sides of the control gate conductive material layers and fourth sides of the semi-floating gate conductive material layers by the first inter-gate dielectric layer; and
the selection gate conductive material layer being isolated from a top surface of the first active area by the selection gate dielectric layer.

14. The method of manufacturing the semi-floating gate transistor according to claim 13, wherein, in the provided semiconductor substrate, a lightly doped source-drain area with a first conductive type is formed in a surface area of the first active area and a doped channel area with a second conductive type located at a bottom of the lightly doped source-drain area;
the semi-floating gate trenches pass through the lightly doped source-drain area and bottom surfaces of the semi-floating gate trenches enter the channel area; the method further comprising:
forming first sidewalls on the first sides of the control gate conductive material layers and third sides of the semi-floating gate conductive material layers, and forming second sidewalls on second side of the selection gate conductive material layer; and
performing heavily doped source-drain implantation with the first conductive type for self-alignment in the lightly doped source-drain area outside the first sidewalls to form a source area and self-alignment in the lightly doped source-drain area outside the second sidewalls to form a drain area.

15. The method of manufacturing the semi-floating gate transistor according to claim 13, wherein a material of the semiconductor substrate comprises silicon;
a material of the semi-floating gate conductive material layers comprises polysilicon;
a material of the control gate conductive material layers comprises polysilicon; and
a material of the selection gate conductive material layer comprises polysilicon.

16. The method of manufacturing the semi-floating gate transistor according to claim 9, wherein, after the control gate patterned etching is completed, the control gate conductive material layers of the storage units aligned in the Y direction are connected together to form a first conductive material strip structure.

17. The method of manufacturing the semi-floating gate transistor according to claim 9, before performing the X direction trench patterned etching, further comprising:
performing blanket etch for the semi-floating gate conductive material layers to thin thicknesses of the semi-floating gate conductive material layers.

18. The method of manufacturing the semi-floating gate transistor according to claim 17, wherein, after the blanket etch for the semi-floating gate conductive material layers is completed, the semi-floating gate conductive material layers extending outside the semi-floating gate trenches have a thickness with a minimum value less than 110 Å.
